(19) United States
(12) Patent Application Publication
(10) Pub. No.: US 2008/0053818 A1
(43) Pub. Date: Mar. 6, 2008

(54) Plasma processing apparatus of substrate and plasma processing method thereof

(75) Inventor: Akio Ui, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA.

(21) Appl. No.: 11/889,518

(22) Filed: Aug. 14, 2007

(30) Foreign Application Priority Data
Aug. 31, 2006 (JP) P2006-237011

(51) Int. Cl. B01J 19/08; B05C 11/00; H01L 21/306

(52) U.S. Cl. 204/164; 118/712; 118/723 E; 156/345.28; 156/345.48

(57) ABSTRACT

A first RF voltage and a second RF voltage are applied to an RF electrode disposed opposite to an opposing electrode in a chamber of which the interior is evacuated under a predetermined vacuum condition from a first RF voltage applying device and a second RF voltage applying device, respectively. The second frequency of the second RF voltage is set to ½×n (n: integral number) of the first frequency of the first RF voltage through the phase control with a gate trigger device so that the first RF voltage is superimposed with the second RF voltage.

### CROSS-REFERENCE TO RELATED APPLICATIONS

This application is based upon and claims the benefit of priority from the prior Japanese Patent Application No. 2006-237011, filed on Aug. 31, 2006; the entire contents of which are incorporated herein by reference.

### BACKGROUND OF THE INVENTION

1. Field of the Invention

The present invention relates to a so-called parallel plate type plasma processing apparatus configured such that the RF electrode is disposed opposite to the opposing electrode and a substrate positioned on the RF electrode is processed by means of plasma which is generated between the RF electrode and the opposing electrode, and to a plasma processing method using the plasma processing apparatus.

2. Description of the Related Art

In the wiring for a substrate such as a semiconductor wafer, it is required that the fine processing is carried out for the substrate before the wiring, and conventionally, in this point of view, a processing apparatus utilizing plasma is often employed for the fine processing.

In the conventional plasma processing apparatus, the high frequency (RF) electrode is disposed opposite to the opposing electrode in the vacuum chamber of which the interior is evacuated in vacuum condition. The substrate to be processed is held on the main surface of the RF electrode which is opposite to the opposing electrode so that the conventional plasma processing apparatus can constitute a parallel plate type plasma processing apparatus. A processing gas to generate the plasma and thus, process the substrate is introduced into the chamber through a gas conduit under a predetermined pressure by vacuum-evacuating the chamber with a vacuum pump through an exhaust line.

Then, a predetermined RF voltage is applied to the RF electrode from a commercial RF power source to generate a high frequency wave of 13.56 MHz so that the intended plasma can be generated between the RF electrode and the opposing electrode.

In this case, since the RF electrode (substrate) is charged negatively so as to be self-biased negatively (the amplitude of the electric potential: Vdc), positive ions are incident onto the substrate at high velocity by means of the negative self-bias of Vdc. As a result, the surface reaction of the substrate is induced by utilizing the substrate incident energy of the positive ions, thereby conducting an intended plasma substrate processing such as reactive ion etching (RIE), CVD (Chemical vapor Deposition), sputtering, ion implantation. Particularly, in view of the processing for the substrate, the RIE can be mainly employed as the plasma substrate processing. Therefore, the RIE processing will be mainly described hereinafter.

In the above-described plasma processing apparatus, since the Vdc (the average substrate incident energy of the positive ions) is increased as the RF power is increased, the RF power is controlled so as to adjust the Vdc for the appropriate processing rate and the shape-forming processing. The Vdc can be adjusted by controlling the pressure in the chamber and the shape of the RF electrode and/or the opposing electrode.

In the above-described plasma processing apparatus, the ion energy in the plasma generated in the chamber is divided into a lower energy side peak and a higher energy side peak so that the energy difference (ΔE) between the peaks becomes within a range of several ten (eV) to several hundred (eV). Therefore, even though the Vdc is adjusted appropriately, some of the ions incident onto the substrate are belonged to the higher energy range and the other of the ions incident onto the substrate are belonged to the lower energy range so that the ions with the higher energy coexist with the ions with the lower energy.

In the plasma substrate processing such as the RIE, in this point of view, the processing shape of the substrate may be deteriorated because some corners of the substrate are flawed by the ions with the higher energy. Moreover, if the ions with the lower energy are employed, the substrate processing may not be conducted because the ion energy becomes below the surface reaction threshold energy or the processing shape of the substrate may be also deteriorated due to the reduction in the processing anisotropy which is originated from that the incident angle range of the ions are enlarged because the thermal velocity of each ion is different from another one.

Recently, semiconductor devices are much downsized so that the films or complex films composing the semiconductor devices are finely processed. Therefore, the processing technique such as the RIE is required to be finely controlled by narrowing the ion energy range (realizing a smaller ΔE) and controlling the average substrate incident energy (Vdc) appropriately.

In order to narrow the ion energy range, it is considered that the intended plasma is generated by developing the frequency of the high frequency wave (refer to JP-A 2003-234331 (KOKAI)) or by utilizing a pulsed wave (refer to J. Appl. Phys. Vol. 88, No. 2, 643(2000)).

The plasma generation can be mainly classified as inductive coupling type plasma generation and capacity coupling type plasma generation. In view of the fine control for the processing shape, it is effective that the plasma volume is decreased so that the plasma retention time can be shortened, thereby reducing the byproduct reaction. As a result, the capacity coupling plasma generation is effective for the fine control for the processing shape in comparison with the inductive coupling plasma generation because the capacity coupling plasma generation can generate only a plasma with a smaller volume than the inductive coupling plasma generation.

It is also considered that two high frequency waves with the respective different frequencies are applied to the RF electrode so that the plasma density can be controlled by the high frequency wave with a higher frequency of e.g., 100 MHz and the Vdc can be controlled by the high frequency wave with a lower frequency of e.g., 3 MHz (refer to JP-A 2003-234331 (KOKAI)). In this case, the plasma density and the Vdc can be finely controlled. Then, two sets of high frequency power sources and matching boxes are prepared for the high frequency waves with the higher frequency and the lower frequency, respectively, so that the high frequency wave with the higher frequency can be superimposed with the high frequency wave with the lower frequency.

In view of the cleaning process and the processing stability, it is desired that the opposing electrode is electrically grounded. If the RF voltage is applied to the opposing electrode, the opposing electrode may be eroded due to the self bias of Vdc applied to the opposing electrode, thereby creating some dusts and render the processing condition unstable. In this point of view, as described above, the two high frequency waves are applied to the RF electrode under the superimposing condition.

[Reference 1] JP-A 2003-234331 (KOKAI)

[Reference 2] G. Chen, L. L. Raja, J. Appl. Phys. 96, 6073(2004)

[Reference 3] J. Appl. Phys. Vol. 88, No. 2, 643(2000)

Such a high frequency technique as examining for ion energy range narrowing is effective for the narrowing of the energy difference ΔE because ions can not follow the electric field from the high frequency wave, but not effective for the enhancement of the Vdc because the absolute value of the Vdc becomes small. For example, if a high frequency wave with a frequency of 100 MHz and an electric power of 2.5 kW is employed (under the condition that the diameter of the susceptor is set to 300 mm, and the pressure in the chamber is set to 50 mTorr using Ar gas), the absolute value of the Vdc is lowered than the Vdc threshold value (about 70 eV) of oxide film or nitride film. Therefore, even though the oxide film and the nitride film is plasma-processed under the condition that the Vdc is lowered than the threshold value, the oxide film and the nitride film can be processed at an extremely processing rate, which can not be practically employed.

On the other hand, if the average substrate incident energy of the positive ions (Vdc) is increased by increasing the RF power, the energy difference ΔE can not be reduced because the Vdc is proportion to the energy difference ΔE during the control of the average substrate incident energy (Vdc) with the RF power. Moreover, the RF power of about 7 kW is required so as to realize the Vdc of 100 V at 100 MHz, which becomes difficult because it is difficult to bring out such a large RF power from a commercially available RF power source with a maximum power within a range of 5 to 10 kW. As a result, the high frequency technique can be applied for such a plasma processing as requiring a lower surface reaction threshold energy, but may not be applied for such a plasma processing as requiring a higher surface reaction threshold energy (70 ev or over) because it is difficult to control the Vdc commensurate with the plasma processing.

In the use of the two high frequency superimposed waves, since the energy difference ΔE is enlarged because the ion energy in the plasma is divided into the lower energy side peak and the higher energy side peak, the energy difference ΔE can not be narrowed.

In the use of the pulsed wave technique, since the ion energy in the plasma is directly controlled by means of the periodically DC voltage, it is advantageous for the ion energy range narrowing and the ion energy control. In this technique, however, since the plasma may be rendered unstable because the applying voltage is remarkably decreased and the plasma density is decreased at DC voltage off-state, and the large current is generated in the plasma when the DC voltage is also applied. Particularly, when an insulator formed on the substrate is plasma-processed, the surface electric charge on the insulator can not be discharged effectively during one period of the DC pulse so that the plasma is rendered unstable and thus, diminished. Moreover, since the large current is generated intermittently in the plasma, the device under fabrication may be electrically damaged, so that a stable parallel plate type pulsed plasma can not be generated.

### BRIEF SUMMARY OF THE INVENTION

It is an object of the present invention, in view of the above-described problems, to provide a parallel plate type substrate plasma processing apparatus wherein the RF electrode is disposed opposite to the opposing electrode in a vacuum chamber so as to generate a plasma with an energy suitable for the substrate processing and a smaller ion energy range enough to process the substrate finely. It is an object of the present invention to provide a substrate plasma processing method utilizing the substrate plasma processing apparatus.

In order to achieve the above object, an aspect of the present invention relates to a substrate plasma processing apparatus, including: a chamber of which an interior is evacuated under a predetermined vacuum condition; an RF electrode which is disposed in the chamber and configured so as to hold a substrate to be processed on a main surface thereof; an opposing electrode which is disposed opposite to the RF electrode in the chamber; an RF applying device for applying a plurality of RF voltages with respective different frequencies to the RF electrode; and a gate trigger device for conducing phase control of the RF voltages so that the plurality of RF voltages are applied to the RF electrode under superimposed condition, wherein, when one RF voltage is one of the plurality of RF voltages, frequencies of the other RF voltages of the plurality of RF voltages are set to ½×n (n: integral number) of a frequency of the one RF voltage.

Another aspect of the present invention relates to a substrate plasma processing method, including: disposing an RF electrode configured so as to hold a substrate to be processed on a main surface thereof in a chamber of which an interior is evacuated under a predetermined vacuum condition; disposing an opposing electrode opposite to the RF electrode in the chamber; applying a plurality of RF voltages with respective different frequencies to the RF electrode; and synchronizing the plurality of RF voltages and conducting phase control of the RF voltages for the plurality of RF voltages so that the plurality of RF voltages are superimposed in a negative pulsed waveform and when one RF voltage is one of the plurality of RF voltages, frequencies of the other RF voltages of the plurality of RF voltages are set to ½×n (n: integral number) of a frequency of the one RF voltage.

Still another aspect of the present invention relates to a substrate plasma processing method, including: disposing an RF electrode configured so as to hold a substrate to be processed on a main surface thereof in a chamber of which an interior is evacuated under a predetermined vacuum condition; disposing an opposing electrode opposite to the RF electrode in the chamber; applying a plurality of RF voltages with respective different frequencies to the RF electrode; and setting, at the time when one RF voltage is one of the plurality of RF voltages, frequencies of the other RF voltages of the plurality of RF voltages are set to ½×n (n: integral number) of a frequency of the one RF voltage so as to control and narrow an average substrate incident ion energy, which is originated from the application of the plurality of RF voltages to the RF electrode, within an energy range suitable for the processing for the substrate.

As described above, according to the present invention can be provided a parallel plate type substrate plasma processing apparatus wherein the RF electrode is disposed opposite to the opposing electrode in a vacuum chamber so as to generate a plasma with an energy suitable for the substrate processing and a smaller ion energy range enough to process the substrate finely. Also, according to the present invention can be provided a substrate plasma processing method utilizing the substrate plasma processing apparatus.

### BRIEF DESCRIPTION OF THE SEVERAL VIEWS OF THE DRAWINGS

FIG. 1 is a structural view schematically illustrating a conventional substrate plasma processing apparatus (Comparative Embodiment).

FIG. 2 is a graph showing the relation between the RF power and the Vdc (average substrate incident energy) in the conventional apparatus illustrated in FIG. 1.

FIG. 3 is a graph representing the characteristics of a plasma originated from the simulation on the basis of the continuum modeled plasma simulator.

FIG. 4 is a graph representing the energy range distribution of the plasma originated from the simulation on the basis of the continuum modeled plasma simulator.

FIG. 5 is a graph showing an ion energy distribution suitable for the substrate processing.

FIG. 6 is a structural view schematically illustrating a substrate plasma processing apparatus according to an embodiment.

FIG. 7 is a schematic view illustrating the waveforms of superimposed high frequency waves to be applied as voltages to the RF electrode of the apparatus illustrated in FIG. 6.

FIG. 8 shows graphs about the waveforms of superimposed high frequency waves, the ion energy variations with time and the ion energy distributions in Example.

FIG. 9 shows graphs about the relation between the phase control (phase shift) and the average ion energy, and the relation between the phase control (phase shift) and the ion energy difference ΔE(ev).

FIG. 10 is a structural view illustrating a modified substrate plasma processing apparatus from the one illustrated in FIG. 6.

FIG. 11 is a structural view illustrating another modified substrate plasma processing apparatus from the one illustrated in FIG. 6.

### DETAILED DESCRIPTION OF THE INVENTION

Hereinafter, the present invention will be described in detail with reference to the drawings.

In the above embodiment, a plurality of RF voltages with the respective different frequencies are applied to the RF electrode under superimposing condition so that, when one RF voltage is selected from the RF voltages, the frequencies of the other RF voltages are set to ½×n (n: integral number) of the frequency of the one RF voltage. In this case, if the RF voltages are appropriately controlled in phase and synchronized, the waveform of the superimposed RF voltage of the RF voltages can be rendered a negative pulsed waveform. Therefore, the resultant negative pulsed voltage is substantially applied to the RF electrode.

In this case, if the frequencies and the voltages of the other RF voltages are controlled in variety for the one selected RF voltage, the conventional lower energy peak can be shifted within an extremely lower energy range which can not affect the substrate processing in comparison with the conventional higher energy peak or the conventional lower energy peak can be shifted in the vicinity of the conventional higher energy peak.

In the former case, when the higher ion energy peak is controlled suitable for the substrate processing, the intended substrate processing can be carried out by utilizing the ions in the higher ion energy peak. That is, if the inherent narrowed energy range characteristic of the higher energy peak is utilized and the higher energy peak is controlled appropriately as described above, the processing shape of the substrate can be controlled finely (First processing method).

In the latter case, since the lower energy peak is shifted in the vicinity of the higher energy peak, it can be considered that the lower energy peak is combined with the higher energy peak, thereby forming one energy peak. That is, when the lower energy peak is shifted in the vicinity of the higher energy peak, the resultant combined energy peak can be considered as one energy peak. Therefore, if the energy range of the one combined energy peak is optimized and the vicinity degree between the lower energy peak and the higher energy peak is optimized, i.e., if the narrowing degree of the energy range of the combined energy peak is optimized, the processing shape of the substrate can be controlled finely by utilizing the combined energy peak (Second processing method).

If the RF frequency of the one selected RF voltage is set to 50 MHz or over, the Vdc (average substrate incident ion energy) can be lowered enough not to affect the substrate processing. In this case, if the frequencies of the RF voltages, which are set to ½×n (n: integral number) of the frequency of the one selected RF voltage, are controlled, the substrate processing can be carried out by utilizing the other RF voltages, whereby the intended substrate processing can be simplified.

In an embodiment, a superimposed waveform monitoring device is provided between the RF electrode and the RF applying device so as to monitor a superimposed waveform of the plurality of RF voltages. In this case, the superimposed state of the plurality of the RF voltages can be successively monitored, and can be adjusted to a desired superimposed state by appropriately controlling the phases of the plurality of RF voltages on the monitored results.

In another embodiment, an ion energy detecting device is provided so as to monitor an energy state of ions located at least between the RF electrode and the opposing electrode (i.e., the energy state of ions incident onto the RF electrode). Therefore, when it is required to vary at least one of the substrate incident ion energy and the ion energy range in the plasma in accordance with the processing stage or processing switching by controlling the frequency and/or voltage of the first RF voltage and/or the second RF voltages the energy condition of the ions in the plasma can be monitored successively.

In the variation in frequency and/or voltage of the RF voltages, the superimposing degree of the RF voltages may be varied. It is required, therefore, to monitor the superimposing degree of the RF voltages successively with the superimposed waveform monitoring device and to control the superimposing degree appropriately.

In the present specification, the “RF applying device” may include an RF generator and an impedance matching box which are known by the person skilled in the art. Moreover, the RF applying device may include an amplifier as occasion demands.

In the present specification, the “pulse applying device” may include an amplifier, a low-pass filter in addition to a pulse generator which is known by the person skilled in the art.

In view of the additional aspects as described above, a substrate plasma processing apparatus and a substrate plasma processing method according to the present invention will be described hereinafter, in comparison with a conventional substrate plasma processing apparatus and method.

### COMPARATIVE EMBODIMENT UTILIZING A SUBSTRATE PLASMA PROCESSING APPARATUS

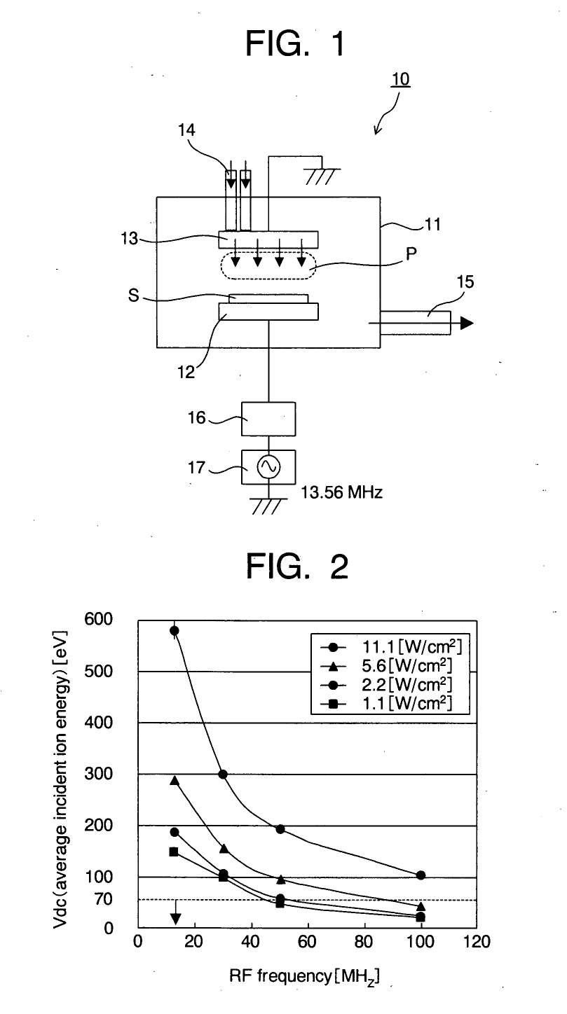

FIG. 1 is a structural view schematically illustrating a conventional substrate plasma processing apparatus in Comparative Embodiment.

In a substrate plasma processing apparatus 10 illustrated in FIG. 1, an high frequency (RF) electrode 12 is disposed opposite to an opposing electrode 13 in a vacuum chamber 11 of which the interior is evacuated under a predetermined degree of vacuum. A substrate S to be processed is positioned on the main surface of the RF electrode 12 which is opposite to the opposing electrode 13. As a result, the substrate plasma processing apparatus 10 constitutes a so-called parallel plate type plasma processing apparatus. A gas for generating plasma and thus, processing the substrate S is introduced in the chamber 11 through a gas conduit 14 designated by the arrows. The interior of the chamber 11 is also evacuated by a vacuum pump (not shown) so that the interior of the chamber 11 can be maintained in a predetermined pressure under the vacuum condition. For example, the interior of the chamber 11 may be set to about 1 Pa.

Then, a predetermined RF voltage is applied to the RF electrode 12 from a commercial RF power source 17 to generate a high frequency wave of 13.56 MHz via a matching box 16 so that the intended plasma P can be generated between the RF electrode 12 and the opposing electrode 13.

In this case, since the RF electrode 12 is charged negatively so as to be self-biased negatively (the amplitude of the electric potential: Vdc), positive ions are incident onto the substrate S positioned on the RF electrode 12 at high velocity by means of the negative self-bias of Vdc. As a result, the surface reaction of the substrate S is induced by utilizing the substrate incident energy of the positive ions, thereby conducting an intended plasma substrate processing such as reactive ion etching (RIE), CVD (Chemical vapor Deposition), sputtering, ion implantation. Particularly, in view of the processing for the substrate, the RIE can be mainly employed as the plasma substrate processing. Therefore, the RIE processing will be mainly described hereinafter.

In the plasma processing apparatus 10 illustrated in FIG. 1, since the Vdc (the average substrate incident energy of the positive ions) is increased as the RF power is increased, as shown in FIG. 2, the RF power is controlled so as to adjust the Vdc for the appropriate processing rate and the shape-forming processing. The Vdc can be adjusted by controlling the pressure in the chamber and the shape of the RF electrode 12 and/or the opposing electrode 13.

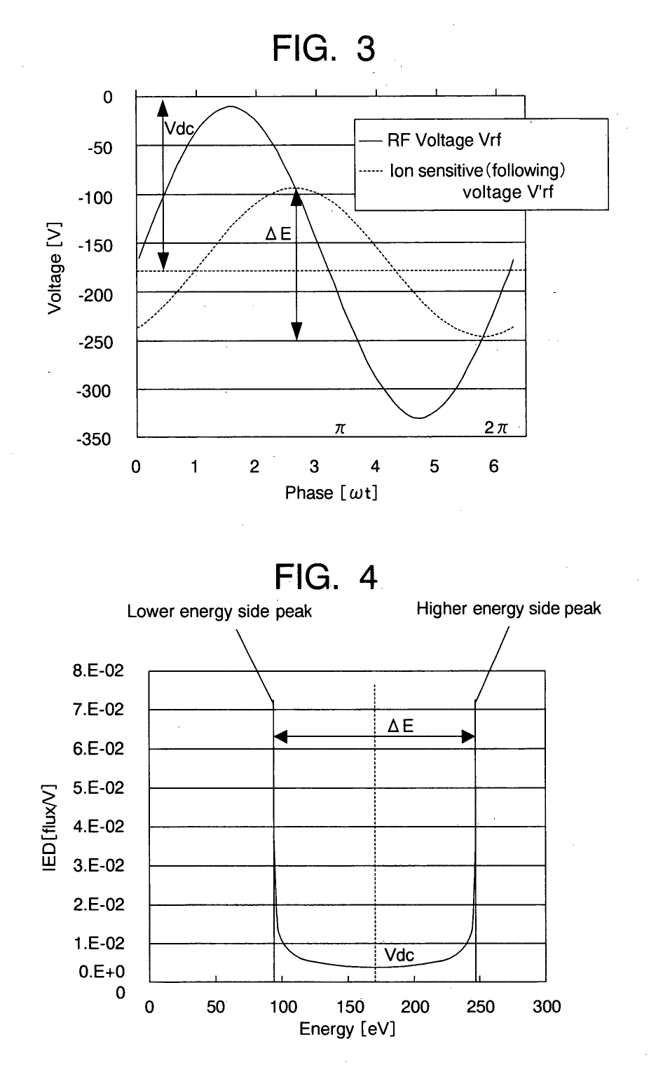

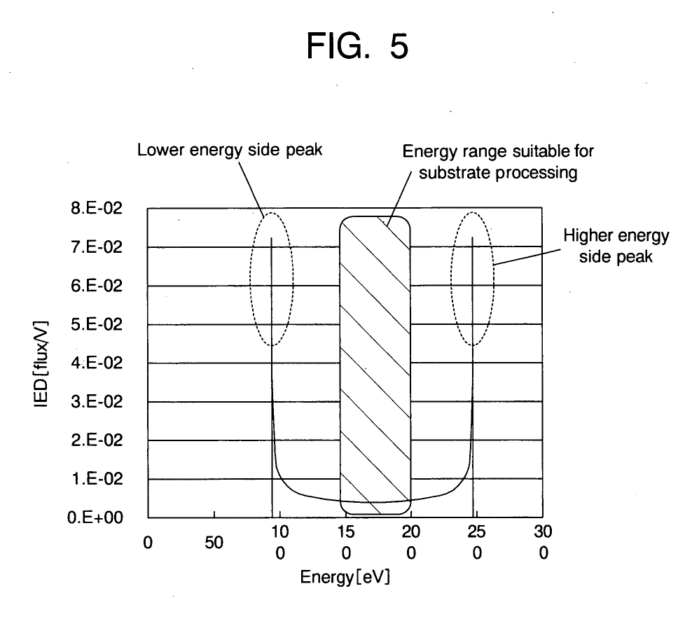

FIGS. 3 and 4 are graphs representing the characteristics of a plasma originated from the simulation on the basis of the continuum modeled plasma simulator (refer to, G. Chen, L. L. Raja, J. Appl. Phys. 96, 6073 (2004)) under the condition that the Ar gas pressure is set to 50 mTorr and the distance between the electrodes is set to 30 mm and the wafer size is set to 300 mm, and the frequency of the high frequency wave is set to 3 MHz and a Vrf of 160 V is employed. FIG. 5 is a graph showing an ion energy distribution suitable for the substrate processing.

As shown in FIG. 3, since the RF electrode potential is periodically varied, the substrate incident ion energy is also periodically varied. However, since the substrate incident ion energy follows the RF electrode potential behind time due to the ion mass, the amplitude Vrf′ of the substrate incident ion energy becomes smaller than the amplitude Vrf of the RE electrode potential. The substrate incident ion energy depends properly on the Vdc and the plasma potential Vp, but since the absolute value and time variation of the Vp are extremely small, the detail explanation for the Vp is omitted in the present specification and the depiction of the Vp is omitted in FIG. 3. As a result, the incident ion energy for the substrate S can be represented as in FIG. 4 by integrating the incident ion energy variation shown in FIG. 3 with time.

As is apparent from FIG. 4, the incident ion energy in the plasma generated in the chamber 11 illustrated in FIG. 1 is divided into the lower energy side peak and the higher energy side peak so that the energy difference ΔE between the peaks can be set within several ten (eV) to several hundred (eV) in dependent on the plasma generating condition. Even though the Vdc is controlled suitable for the intended substrate processing, therefore, with the substrate incident ions, the ions within a higher energy range (higher energy side peak) coexists with the ions within a lower energy range (lower energy side peak), as shown in FIG. 5.

In the plasma substrate processing such as the RIE, in this point of view, the processing shape of the substrate S may be deteriorated because some corners of the substrate S are flawed by the ions with the higher energy. Moreover, if the ions with the lower energy are employed, the substrate processing may not be conducted because the ion energy becomes below the surface reaction threshold energy or the processing shape of the substrate may be also deteriorated due to the reduction in the processing anisotropy which is originated from that the incident angle range of the ions are enlarged because the thermal velocity of each ion is different from another one.

### EMBODIMENT UTILIZING A SUBSTRATE PLASMA PROCESSING APPARATUS

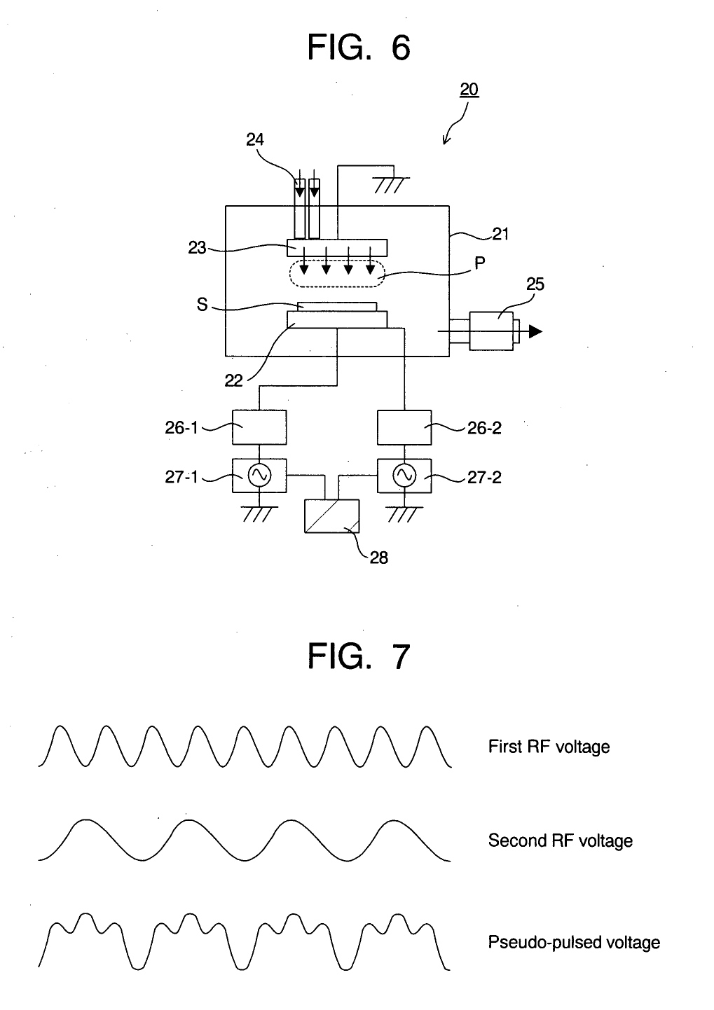

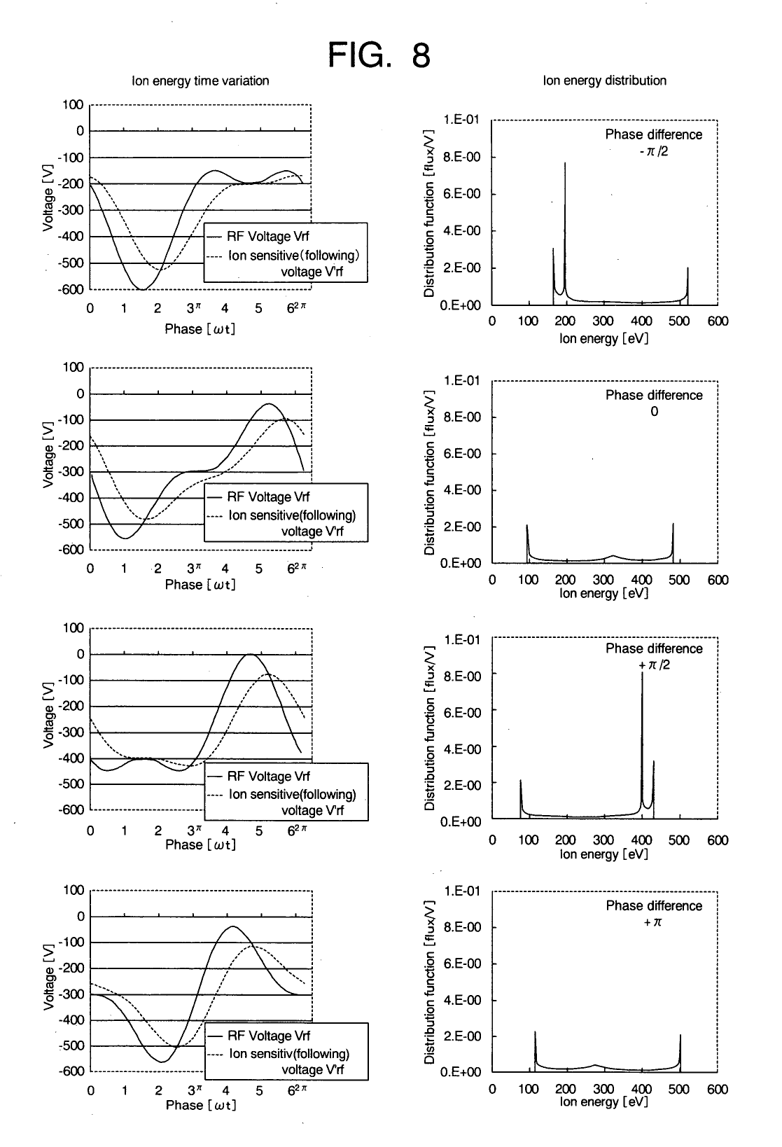

FIG. 6 is a structural view schematically illustrating a substrate plasma processing apparatus according to an embodiment. FIG. 7 is a schematic view illustrating the waveforms of superimposed high frequency waves to be applied as voltages to the RF electrode of the apparatus illustrated in FIG. 6. The RIE processing will be mainly described hereinafter as a plasma processing method utilizing the plasma processing apparatus illustrated in FIG. 6.

In a substrate plasma processing apparatus 20 illustrated in FIG. 6, an high frequency (RF) electrode 22 is disposed opposite to an opposing electrode 23 in a vacuum chamber 21 of which the interior is evacuated under a predetermined degree of vacuum. A substrate S to be processed is positioned on the main surface of the RF electrode 22 which is opposite to the opposing electrode 23. As a result, the substrate plasma processing apparatus 20 constitutes a so-called parallel plate type plasma processing apparatus. A gas for generating plasma and thus, processing the substrate S is introduced in the chamber 21 through the gas conduit 24 designated by the arrows. The interior of the chamber 21 is also evacuated by a vacuum pump (not shown) through an exhaust line 25 so that the interior of the chamber 11 can be maintained in a predetermined pressure under the vacuum condition.

As the gas, such a gas as Ar, Kr, Xe, N₂, O₂, CO, H₂ can be employed, and more, such a processing gas as SF₆, CF₄, C₂F₆, C₄F₈, C₅F₈, C₄F₆, Cl₂, HBr, SiH₄, SiF₄ can be employed.

Then, a first RF voltage with a first frequency is applied to the RF electrode 22 from a first RF power source 27-1 via a first matching box 26-1 while a second RF voltage with a second frequency is applied to the RF electrode 22 from a second RF power source 27-2 via a second matching box 26-2. The first RF power source 27-1 and the second RF power source 27-2 are connected to a gate trigger device 28 so that the phases of the first RF voltage and the second RF voltage can be controlled appropriately with the device 28.

In this embodiment, the second frequency of the second RF voltage is set different from the first frequency of the first RF voltage so that the second frequency can be set to ½×n (n: integral number) of the first frequency. In this case, the phase shift of the first RF voltage and/or the second RF voltage per period can be prevented.

Suppose that the second frequency of the second RF voltage is set as high as half of the first frequency of the first RF voltage, the pseudo-pulsed voltage is generated by superimposing the first RF voltage and the second voltage as shown in FIG. 7, and thus, is applied to the RF electrode 22. In this case, a plasma P is generated between the RF electrode 22 and the opposing electrode 23 so that the positive ions in the plasma P are incident onto the substrate S on the RF electrode 22 and thus, the substrate S is processed by means of the incident positive ions.

The RF power sources 27-1 and 27-1 may include the respective amplifiers therein to amplify the RF voltages and/or the resultant pulsed voltage as occasion demands.

The matching boxes 26-1 and 26-2 may include the respective filter circuits so that the resultant RF signals (voltages) are not returned to the RF power sources 27-1 and 27-2 from the RF electrode 22 by shutting off the RF signals and the intended RF voltages are applied to the RF electrode 22 from the RF power sources 27-1 and 27-2 through the filter circuits.

If the energy value and energy width in the energy distribution are optimized and the distribution in the ion flux amount is optimized, the energy difference ΔE can be reduced. Such parameters as described above can be adjusted appropriately by controlling the amplitudes (voltage values) and phases of the first RF voltage and the second RF voltage.

With the plasma etching, e.g., for silicon substrate, a relative large ion energy of about 200 eV is required so as to remove the surface naturally oxidized film, and then, a relatively small ion energy of about 100 eV is preferably required so as to realize the etching process, and then, a much smaller ion energy of about 70 eV is preferably required so as to realize the fine etching process after the stopper such as oxide film is exposed. Such a stepwise ion energy switching can be performed by varying the frequency ω2 of the second RF voltage and/or the amplitude (voltage value) V_{RF2} of the second RF voltage.

### EXAMPLE

The present invention will be concretely described with reference to Example, but the present invention is not limited to Example. Hereinafter, the concrete results are originated from a predetermined simulation.

In Example, the concrete operational characteristics relating to the plasma processing apparatus illustrated in FIG. 6 were investigated.

First of all, a C₄F₈ gas and an oxygen gas were introduced in the chamber 21 so that the interior of the chamber 21 was set to a pressure within a range of 2 to 200 mTorr. Then, the first RF voltage with the amplitude V_{RF1} of 100 V and the first frequency of 4 MHz was applied to the RF electrode 22 from the first RF power source 27-1 while the second RF voltage with the amplitude V_{RF2} of 200 V and the second frequency of 2 MHz was applied to the RF electrode 22 from the second RF power source 27-2 via a second matching box 26-2. The phases of the first RF voltage and the second RF voltage were controlled by the gate trigger device 28 and thus, superimposed.

FIG. 8 shows the simulated results such as the waveform of the superimposed RF voltage, the time variation of ion energy and the ion energy distribution which relate to the superimposed RF voltage. In FIG. 8, the input superimposed voltage Vrf, the sensitive and following voltage of ions in the plasma (i.e., the substrate incident ion energy as eV unit is employed) (left side) and the ion energy distribution in the plasma (right side) are depicted when the phase difference δ2−δ1 is set to −π/2, 0, +π/2, π from the top view to the bottom view under the condition that the Vrf1 of the first RF voltage is represented as Vrf1=sin(ω1·t+δ1) and the Vrf2 of the second RF voltage is represented as Vrf2=sin(ω2·t+δ2).

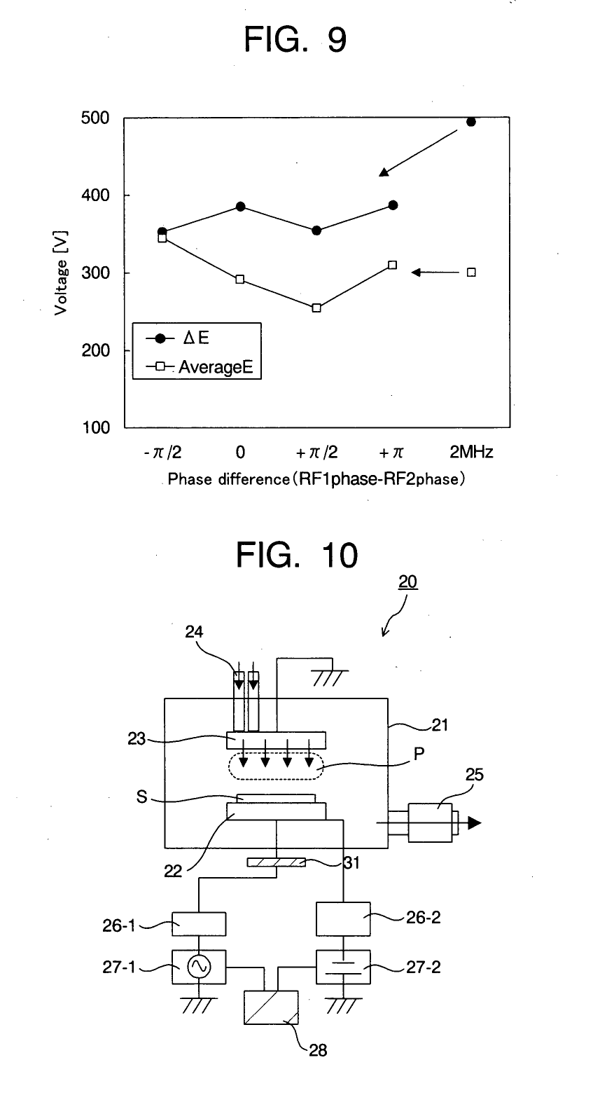

FIG. 9 shows graphs about the relation between the phase control (phase difference) and the average ion energy, and the relation between the phase control (phase difference) and the ion energy difference ΔE (eV) in Examples. The average ion energy corresponds to the Vdc in FIG. 4 and means the average value (energy midpoint) of the ion energy distribution.

It is apparent from FIG. 8 that the convex pseudo pulsed voltage can be generated at the phase difference=+π/2 and the concave pseudo pulsed voltage can be generated at the phase difference=−π/2 (refer to the left side in FIG. 8). As a result, the energy difference ΔE can be narrowed when the pulsed voltages are generated at the phase difference=−π/2 and +π/2 (refer to FIG. 9). Then, it is apparent from FIG. 8 that the phase difference can vary the ion energy distribution (e.g., the higher energy range-inclined distribution or the lower energy range-inclined distribution), thereby simplifying the plasma processing.

Suppose that the plasma density N₀ is set to 5×10¹⁶ [/m³] and the self-bias is set to −200 V, the pseudo-pulsed voltages at the phase difference=−π/2 and +π/2 can be generated so that the energy difference ΔE can be narrowed by about 30 (eV) and the energy range can be narrowed by about 150 (eV) in comparison with a single RF voltage with a frequency of 2 MHz. Moreover, the average ion energy can be shifted by about 100 (eV) due to the phase difference control (the phase difference=−π/2 and +π/2).

In addition, as shown in the right side in FIG. 8, the shape of the ion energy distribution is varied dependent on the phase difference. Therefore, the shape of the ion energy distribution can be varied suitable for the intended plasma processing by controlling the phases (phase difference) so that the large amount of flux is positioned at the energy range suitable for the intended plasma processing. The ion energy distribution can be monitored by the ion energy monitor.

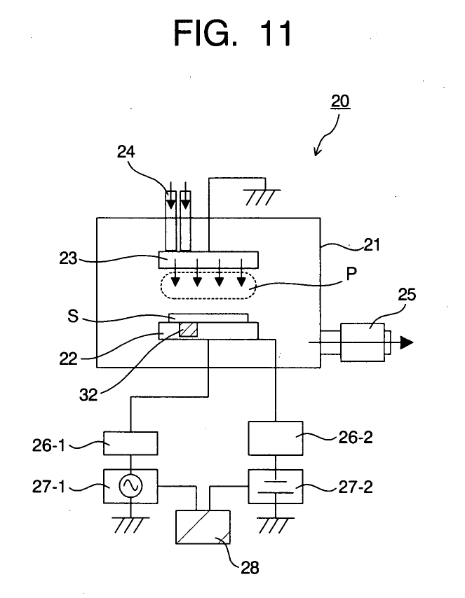

FIGS. 10 and 11 are structural views illustrating modified substrate plasma processing apparatuses from the one illustrated in FIG. 6. The plasma processing apparatus illustrated in FIG. 10 is different from the one illustrated in FIG. 6 in that a superimposed waveform monitoring device 31 is provided between the RF electrode 22 and the RE power sources 27-1, 27-2. The plasma processing apparatus illustrated in FIG. 11 is different from the one illustrated in FIG. 6 in that an ion energy monitor 32 is built in the RF electrode 22. For simplification, the same reference numerals are imparted to corresponding or like components through FIGS. 6, and 10 to 11.

In the plasma processing apparatus 20 illustrated in FIG. 10, the superimposed condition of the first RF voltage and the second RF voltage can be monitored so as to be an intended superimposed condition by controlling the phases of the first RF voltage and the second RF voltage in accordance with the monitored superimposed condition.

In the plasma processing apparatus 20 illustrated in FIG. 11, the energy condition of the ions located at least between the RF electrode 22 and the opposing electrode 23 can be monitored with the ion energy monitor 32. Therefore, when it is required to vary at least one of the substrate incident ion energy and the ion energy range in the plasma in accordance with the processing stage or processing switching by controlling the frequency and/or voltage of the first RF voltage and/or the second RF voltage the energy condition of the ions in the plasma can be monitored successively.

In the variation, since the superimposed degree of the first RF voltage and the second RF voltage may be changed, it is desired in the case that the superimposed degree is monitored with the superimposed waveform monitoring device and thus, controlled on the monitored results.

Although the present invention was described in detail with reference to the above examples, this invention is not limited to the above disclosure and every kind of variation and modification may be made without departing from the scope of the present invention.

In these embodiments, for example, the plasma processing apparatus and method of the present invention is directed mainly at RIE technique, but may be applied for another processing technique.

For example, if three RF applying device are employed, the superimposed RF waveform can be rendered a steep negative pulsed waveform and thus, the ion energy range can be narrowed more effectively.

What is claimed is:

1. A substrate plasma processing apparatus, comprising:
a chamber of which an interior is evacuated under a predetermined vacuum condition;
an RF electrode which is disposed in said chamber and configured so as to hold a substrate to be processed on a main surface thereof;
an opposing electrode which is disposed opposite to said RF electrode in said chamber;
an RF applying device for applying a plurality of RF voltages with respective different frequencies to said RF electrode; and
a gate trigger device for conducing phase control of said RF voltages so that said plurality of RF voltages are applied to said RF electrode under superimposed condition,
wherein, when one RF voltage is one of said plurality of RF voltages, frequencies of the other RF voltages of said plurality of RF voltages are set to ½×n (n: integral number) of a frequency of the one RF voltage.

2. The apparatus as set forth in claim 1,
wherein a waveform of the resultant superimposed RF voltage is rendered a negative pulsed shape through said phase control of said gate trigger.

3. The apparatus as set forth in claim 1,
wherein an ion energy in a plasma generated between said RF voltage applying device and said opposing electrode is divided into a higher energy side peak and a lower energy side peak so that an energy difference between said higher energy side peak and said lower energy side peak is changeable by controlling said frequencies and voltages for said one selected RF voltage.

4. The apparatus as set forth in claim 3,
wherein said higher energy side peak is shifted so that ions only within said higher energy side peak can be utilized for substrate processing.

5. The apparatus as set forth in claim 3,
wherein said lower energy peak is shifted in the vicinity of said higher energy peak so that it can be considered that said lower energy peak is combined with said higher energy peak, thereby forming one energy peak, and ions within the thus obtained one energy peak is utilized for substrate processing.

6. The apparatus as set forth in claim 1,
wherein a frequency of said one RF voltage selected is set to 50 MHz or below so that the other RF voltages of said plurality of RF voltages can be utilized for substrate processing.

7. The apparatus as set forth in claim 1, further comprising
a superimposed waveform monitoring device for monitoring a superimposed waveform of said plurality of RF voltages which is located between said RF electrode and said RF applying device.

8. The apparatus as set forth in claim 1, further comprising
an ion energy detecting device for monitoring an energy state of ions incident at least onto said RF electrode.

9. A substrate plasma processing method, comprising:
disposing an RF electrode configured so as to hold a substrate to be processed on a main surface thereof in a chamber of which an interior is evacuated under a predetermined vacuum condition;
disposing an opposing electrode opposite to said RF electrode in said chamber;
applying a plurality of RF voltages with respective different frequencies to said RF electrode; and
synchronizing said plurality of RF voltages and conducting phase control of said RF voltages for said plurality of RF voltages so that said plurality of RF voltages are superimposed in a negative pulsed waveform and when one RF voltage is one of said plurality of RF voltages, frequencies of the other RF voltages of said plurality of RF voltages are set to ½×n (n: integral number) of a frequency of the one RF voltage.

10. The method as set forth in claim 9,
wherein a waveform of the resultant superimposed RF voltage is rendered a negative pulsed shape through said phase control.

11. The method as set forth in claim 9,
wherein an ion energy in a plasma generated between said RF voltage applying device and said opposing electrode is divided into a higher energy side peak and a lower energy side peak so that an energy difference between said higher energy side peak and said lower energy side peak is changeable by controlling said frequencies and voltages for said one selected RF voltage.

12. The method as set forth in claim 11,
wherein said higher energy side peak is shifted so that ions only within said higher energy side peak can be utilized for substrate processing.

13. The method as set forth in claim 11,
wherein said lower energy peak is shifted in the vicinity of said higher energy peak so that it can be considered that said lower energy peak is combined with said higher energy peak, thereby forming one energy peak, and ions within the thus obtained one energy peak is utilized for substrate processing.

14. The method as set forth in claim 9,
wherein a frequency of said one RF voltage selected is set to 50 MHz or below so that the other RF voltages of said plurality of RF voltages can be utilized for substrate processing.

15. A substrate plasma processing method, comprising:
disposing an RF electrode configured so as to hold a substrate to be processed on a main surface thereof in a chamber of which an interior is evacuated under a predetermined vacuum condition;
disposing an opposing electrode opposite to said RF electrode in said chamber;
applying a plurality of RF voltages with respective different frequencies to said RF electrode; and
setting, at the time when one RF voltage is one of said plurality of RF voltages, frequencies of the other RF voltages of said plurality of RF voltages are set to ½×n (n: integral number) of a frequency of the one RF voltage so as to control and narrow an average substrate incident ion energy, which is originated from the application of said plurality of RF voltages to said RF electrode, within an energy range suitable for the processing for said substrate.

16. The method as set forth in claim 15,
wherein a waveform of the resultant superimposed RF voltage is rendered a negative pulsed shape through said phase control of said RF voltages.

17. The method as set forth in claim 15,
wherein an ion energy in a plasma generated between said RF voltage applying device and said opposing electrode is divided into a higher energy side peak and a lower energy side peak so that an energy difference between said higher energy side peak and said lower energy side peak is changeable by controlling said frequencies and voltages for said one selected RF voltage.

18. The method as set forth in claim 17,
wherein said higher energy side peak is shifted so that ions only within said higher energy side peak can be utilized for substrate processing.

19. The method as set forth in claim 17,
wherein said lower energy peak is shifted in the vicinity of said higher energy peak so that it can be considered that said lower energy peak is combined with said higher energy peak, thereby forming one energy peak, and ions within the thus obtained one energy peak is utilized for substrate processing.

20. The method as set forth in claim 15,
wherein a frequency of said one RF voltage selected is set to 50 MHz or below so that the other RF voltages of said plurality of RF voltages can be utilized for substrate processing.
